(19) United States
(12) Patent Application Publication
(10) Pub. No.: US 2011/0062470 A1
(43) Pub. Date: Mar. 17, 2011

(54) REDUCED ANGULAR EMISSION CONE ILLUMINATION LEDS

(75) Inventors: Serge J. BIERHUIZEN, Santa Rosa, CA (US); M. George CRAFORD, Los Altos Hills, CA (US)

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/561,517

(22) Filed: Sep. 17, 2009

(51) Int. Cl. H01L 33/00; H01L 21/00

(52) U.S. Cl. 257/98; 438/29; 257/E21.001; 257/E33.001

(57) ABSTRACT

A light emitting diode (LED) package includes a support, an LED die mounted on the support, a reflector around the LED die, and a lens over the LED die. The reflector has an angled reflective surface that limits the light emission angle from the LED package. The reflector is a part of the lens or the support.

### FIELD OF INVENTION

The present disclosure relates to light emitting diode (LED) packages and, in particular, to LED packages that meets glare regulations for overhead lighting.

### DESCRIPTION OF RELATED ART

Overhead lighting fixtures may have to meet glare regulations that limit brightness over certain emission angle (e.g., less than 1000 cd/m² for angles greater than 65 degrees). Some lighting fixtures use diffusers to limit their emission angles. These diffusers may impact the aesthetics of the lighting fixtures by increasing the thickness of the lighting fixtures.

More and more lighting fixtures are using light emitting diodes (LEDs) are their light source because LEDs are energy efficient and have a long life. LEDs typically generate Lambertian emissions that do not meet the glare regulations for overhead lighting. Thus, what are needed are LEDs that generate radiation patterns that meet glare regulations for overhead lighting.

### SUMMARY

In one or more embodiments of the present disclosure, a light emitting diode (LED) package includes an integrated package level reflector formed around an LED die. The reflector reduces the light emission angle of the LED package so the LED package may be used as a light source in overhead light fixtures.

### BRIEF DESCRIPTION OF THE DRAWINGS

In the drawings:

FIG. 1 illustrates a cross-sectional view of an LED package with a lens integrated with a package level reflector;

FIG. 2A illustrates a cross-sectional view of the lens of FIG. 1;

FIG. 2B illustrates an enlarged portion of FIG. 2A showing an encapsulation/bonding material between a wavelength converting element and the lens;

FIG. 3 is a flowchart of a method for fabricating the LED package of FIG. 1;

FIG. 4 illustrates a cross-sectional view of an LED package with a package level reflector molded on a support for the LED die;

FIG. 5 is a flowchart of a method for fabricating the LED package of FIG. 4;

FIG. 6 illustrates a cross-sectional view of an LED package with a support integrated with a package level reflector; and

FIG. 7 is a flowchart of a method for fabricating the LED package of FIG. 6, all arranged in accordance with embodiments of the present disclosure.

Use of the same reference numbers in different figures indicates similar or identical elements.

### DETAILED DESCRIPTION

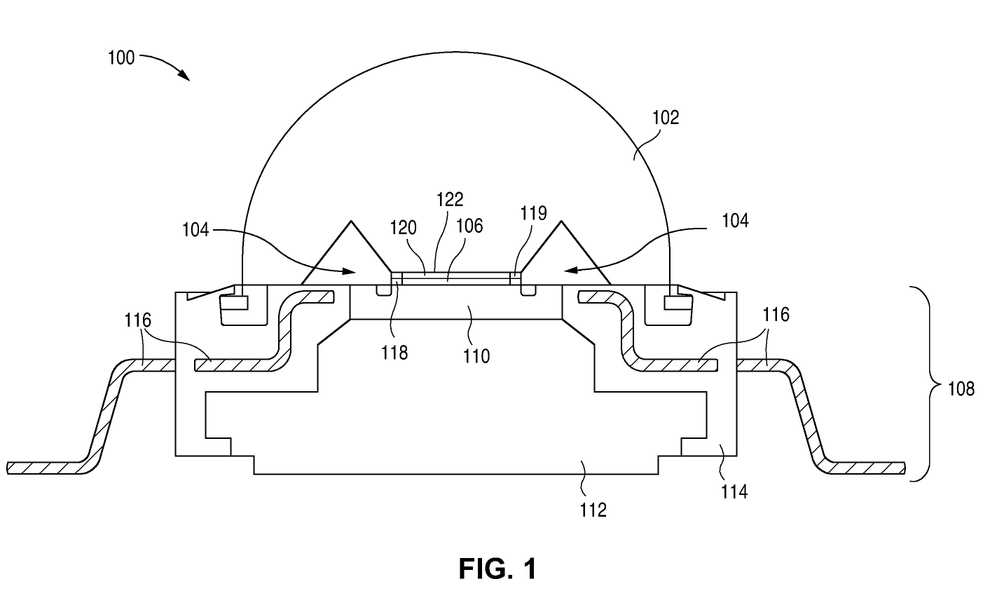

FIG. 1 illustrates a cross-sectional view of a light emitting diode (LED) package 100 with a lens 102 integrated with an integrated package level reflector 104 in one or more embodiments of the present disclosure. Lens 102 encapsulates an LED die 106 on a support 108. Support 108 may include a submount or interposer 110, a heat sink 112, and a leadframe or housing 114. LED die 106 is mounted on interposer 110. Interposer 110 has conductive traces that electrically couple LED die 106 to bond wire pads on the interposer. Interposer 110 is mounted on heat sink 112. Heat sink 112 dissipates heat from LED die 106. Heat sink 112 is received in housing 114. Bond wires (not shown) electrically couple the pads on interposer 110 to electrical leads 116 of housing 110, which pass electrical signals between LED package 100 and external components.

LED die 106 may include an n-type layer, a light-emitting layer (common referred to as the “active region”) over the n-type layer, a p-type layer over the light-emitting layer, a conductive reflective layer over the p-type layer, and a guard metal layer over the conductive reflective layer. One or more n-type bond pads provide electrically contact to the n-type layer, and one or more p-type bond pads provide electrical contact to the conductive reflective layer for the p-type layer. The lateral sides of LED die 106 are covered by a reflective or scattering coating 118 to limit edge emission. Coating 118 may be a polymer or a resin with reflective particles, such as silicone, epoxy, or acrylic with TiO₂. Coating 118 may also be a thin metal film such as Al, Ag, Cr, Au, Ni, V, Pt, Pd, or a combination thereof.

A wavelength converting element 120 may be located over LED die 106 to modify the emission spectrum and provide a desired color light. Wavelength converting element 120 may be one or more phosphor layers applied to the top of LED die 106, or one or more ceramic phosphor plates bonded to the top of the LED die. Ceramic phosphor plates are described in detail in U.S. Pat. No. 7,361,938, which is commonly assigned and incorporated herein by reference. An encapsulation/bonding material may be placed between lens 102 and wavelength converting element 120. The encapsulation/bonding material may be a silicone having a refractive index of 1.33 to 1.53.

Instead of being bonded to LED die 106, the ceramic phosphor plates may be bonded to lens 102 as described in U.S. patent application Ser. No. ______ entitled “Molded Lens Incorporating a Window Element,” attorney docket no. PH012893US1, which is concurrently filed, commonly assigned, and incorporated herein by reference. The lateral sides of wavelength converting element 120 are covered by a reflective or scattering coating 119 to limit edge emission. Coating 119 may be the same material as coating 118, and they may be applied at the same time. An encapsulation/bonding material may be placed between wavelength converting element 120 and LED die 106 when lens 102 is mounted on support 108. The encapsulation/bonding material may be a silicone having a refractive index of 1.33 to 1.53.

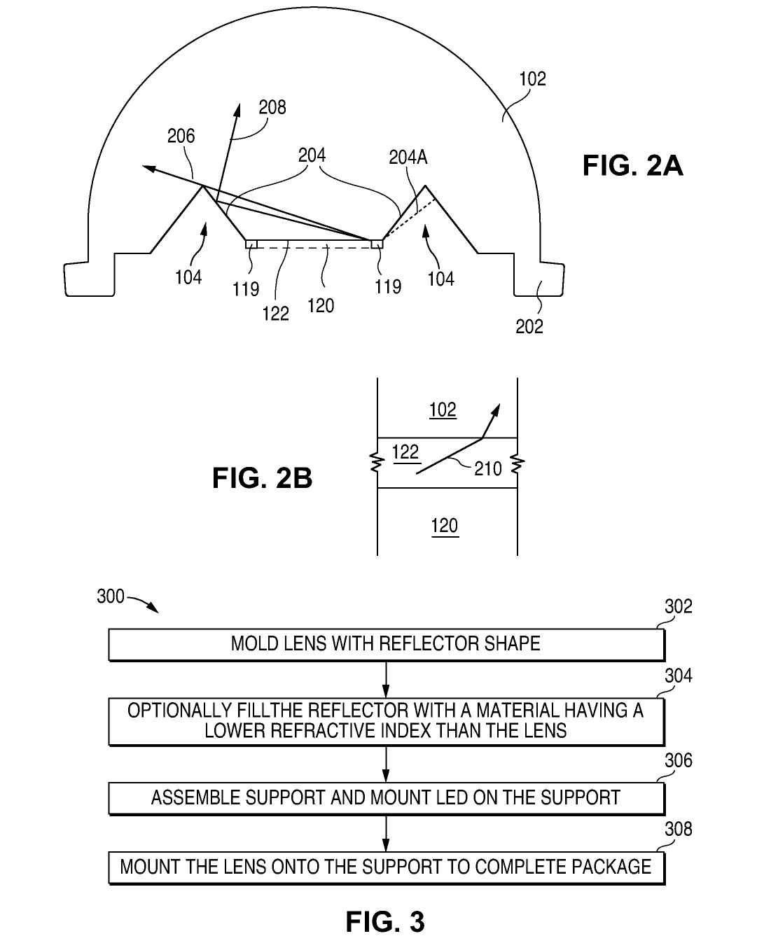

FIG. 2A illustrates a cross-sectional view of lens 102 in one or more embodiments of the present disclosure. Lens 102 is solid and has a dome shape that improves light extraction. Lens 102 has a flange 202 around the perimeter of its bottom surface that fits into a groove in housing 114. Lens 102 may be a material with a refractive index similar to the underlying element to improve light extraction. Lens 102 may be glass with a refractive index of 1.5 to 1.8.

Reflector 104 is one or more cavities formed in the bottom surface of lens 102. Reflector 104 is filled with air or a material having a lower refractive index than lens 102. One or more reflective surfaces 204 are created at the medium boundary between lens 102 and reflector 104 from total internal reflection (TIR). The lower index material may be a silicone with a refractive index of 1.33 to 1.53. The silicone may also serve as an adhesive and an encapsulation material between lens 102 and support 108. Instead of utilizing coatings 118 and 119 to limit edge emission from LED die 106 and wavelength converting element 120, the lower index material may include reflective particles to serve the same function. The reflective particles may be TiO₂.

Reflective surfaces 204 reflects light emitted from LED die 106 or wavelength converting element 120 to limit the emission angle of LED package 100, as demonstrated by light rays 206 and 208. The shapes of reflective surfaces 204 depend on the desired emission angle of LED package 100. Reflective surfaces 204 may be flat or curved, and they may be asymmetrical (as demonstrated by reflective surface 204 and phantom reflective surface 204A).

FIG. 2B shows that encapsulation/bonding material 122 may refract a light ray 210 as it travels from encapsulation/bonding material 122 to lens 102. The refractive index of encapsulation/bonding material 122 may be less than the refractive index of lens 102. The shape of reflective surfaces 204 may need to consider any refraction of the light at the interface between encapsulation/bonding material 122 and lens 102 in order to produce the desired emission angle of LED package 100.

Referring back to FIG. 2A, reflector 104 has the same layout as LED die 106 or wavelength converting element 120 so the reflector is located immediately adjacent to the final light emitting surface once lens 102 is mounted on support 108. For example, reflector 104 may have a triangular cross-section with flat reflective surfaces 204. The shape of reflector 104 and reflective surfaces 204 may be determined using an optical design software, such as LightTools from Optical Research Associates of Pasadena, Calif.

FIG. 3 is a flowchart of a method 300 for fabricating LED package 100 in one or more embodiments of the present disclosure. In process 302, lens 102 is molded with reflector 104. Process 302 is followed by process 304.

In process 304, reflector 104 is optionally filled with a material having a lower refractive index than lens 102. Alternatively reflector 104 is left empty so it is filled with air after lens 102 is mounted on support 108. Process 304 is followed by process 306.

In process 306, support 108 is assembled from interposer 110, heat sink 112, and housing 114, and LED die 106 is mounted on the interposer of the support. Wavelength converting element 120 may be formed on or bonded to the top of LED die 106 before the LED is mounted on support 108. The lateral sides of LED die 106 and the wavelength converting element 120 are then covered by reflective or scattering coatings 118 and 119. Process 306 is followed by process 308.

In process 308, lens 102 is mounted on support 108 to encapsulate LED die 106 and wavelength converting element 120 to complete LED package 100. Flange 202 of lens 102 is fit into a groove in housing 114 and an outer portion of the groove is plastically deformed over the flange to secure and seal the lens to the housing. As described above, an encapsulation/bonding material may be placed between lens 102 and wavelength converting element 120.

In method 300, reflector 104 may be filled with the lower index material after lens 102 is mounted to support 108 through conduits in housing 114. In method 300, wavelength converting element 120 may also be bonded to lens 102 instead of LED die 106. As described above, an encapsulation/bonding material may be placed between wavelength converting element 120 and LED die 106.

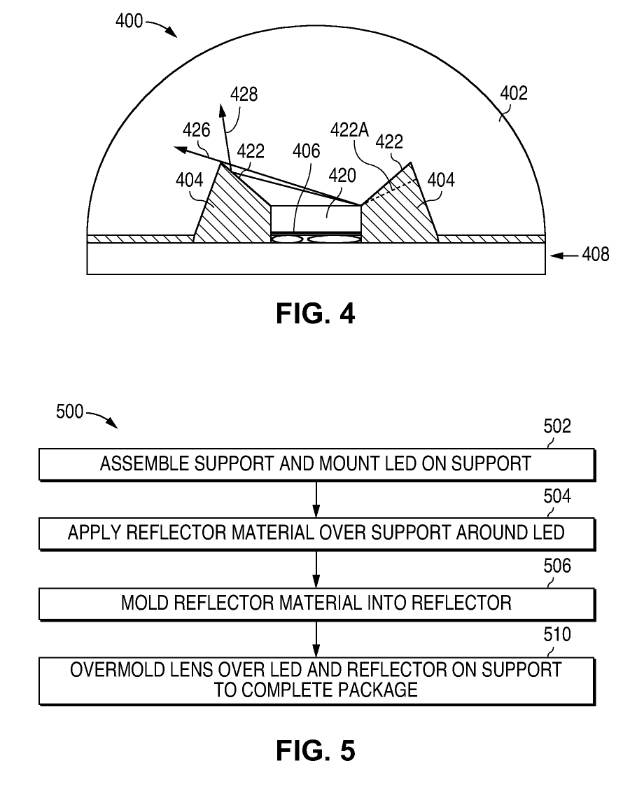

FIG. 4 illustrates a cross-sectional view of an LED package 400 with a package level reflector 404 molded on a support 408 for an LED die 406 in one or more embodiments of the present disclosure. Although not shown, support 408 may include an interposer, a heat sink, and a housing as described above for support 108. LED die 406 may be similarly constructed as LED die 106.

A wavelength converting element 420 may be located over LED die 406 to modify the emission spectrum and provide a desired color light. Wavelength converting element 420 may be one or more phosphor layers applied to the top of LED die 406, or one or more ceramic phosphor plates bonded to the top of the LED die. Ceramic phosphor plates are described in detail in U.S. Pat. No. 7,361,938, which is commonly assigned and incorporated herein by reference.

A silicone lens 402 is molded over support 408 to encapsulate LED die 406 and reflector 404. Reflector 404 may be a low index silicone having a refractive index of 1.33 to 1.53, and lens 402 may be a high index silicone having a refractive index of 1.41 to 1.7. The silicone of reflector 404 may include reflective particles to add a scattering property to the reflector. The reflective particles may be TiO₂. The scattering property of reflector 404 is used to limit edge emission from LED die 406 and wavelength converting element 420.

One or more angled reflective surfaces 422 are created at the medium boundary between lens 402 and reflector 404 from total internal reflection. Reflective surfaces 422 reflect light emitted from LED die 406 or wavelength converting element 420 to limit the emission angle of LED package 400, as demonstrated by light rays 426 and 428. The shape of reflective surfaces 422 depends on the desired emission angle of LED package 400. Reflective surfaces 422 may be flat or curved, and they may be asymmetrical (as demonstrated by reflective surface 422 and phantom reflective surface 422A). Reflector 404 generally follows the perimeter of LED die 406 or wavelength converting element 420 so the reflector is located immediately adjacent to the final light emitting surface. The shape of reflector 404 and reflective surfaces 422 may be determined using an optical design software, such as LightTools from Optical Research Associates of Pasadena, Calif.

FIG. 5 is a flowchart of a method 500 for fabricating LED package 400 in one or more embodiments of the present disclosure. In process 502, support 408 is assembled from its components, if any, and LED 406 is mounted on the support. Wavelength converting element 420 may be formed on or bonded to the top of LED 406 before the LED is mounted on support 408. Process 502 is followed by process 504.

In process 504, the reflector material is applied over support 408 around LED die 406 and wavelength converting element 420. Process 504 is followed by process 506.

In process 506, the reflector material is molded to form reflector 404. A mold may be pressed onto the reflector material to form reflector 404. Process 506 is followed by process 508.

In process 508, lens 402 is molded over support 408 to encapsulate LED 406, wavelength converting element 420, and reflector 402 to complete LED package 400.

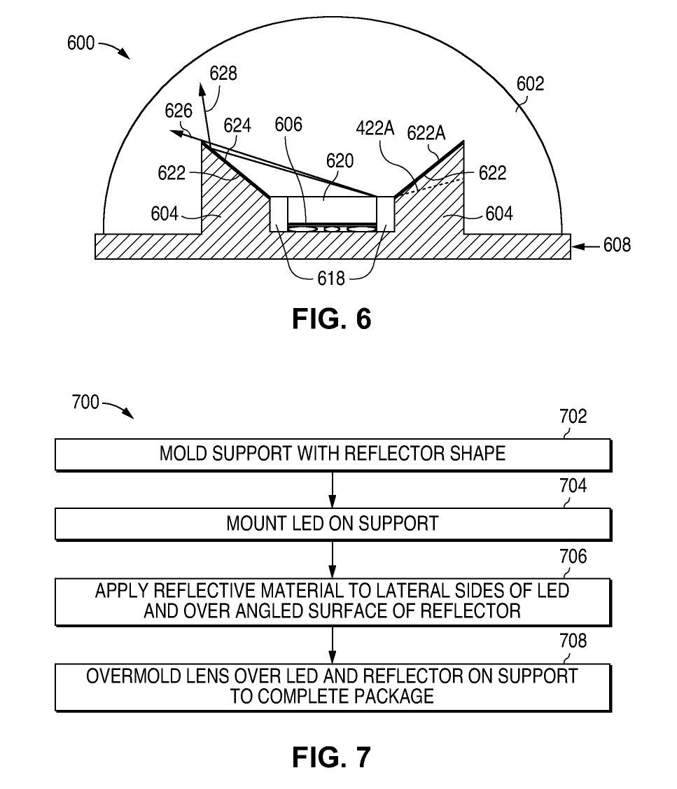

FIG. 6 illustrates a cross-sectional view of an LED package 600 with a support 608 integrated with a package level reflector 604 in one or more embodiments of the present disclosure. Support 608 may be a leadframe or an interposer such as a metal core printed circuit board (MCPCB). An LED die 606 is mounted on support 608. LED die 606 may be similarly constructed as LED die 106.

A wavelength converting element 620 may be located over LED die 606 to modify the emission spectrum and provide a desired color light. Wavelength converting element 620 may be one or more phosphor layers applied to the top of LED die 606, or one or more ceramic phosphor plates bonded to the top of the LED die. Ceramic phosphor plates are described in detail in U.S. Pat. No. 7,361,938, which is commonly assigned and incorporated herein by reference.

The lateral sides of LED die 606 and wavelength converting element 620 are covered by a reflective or scattering coating 618 to control edge emission. Coating 618 may be a polymer or a resin with reflective particles, such as silicone, epoxy, or acrylic with TiO₂. Coating 618 may also be a thin metal film such as Al, Ag, Cr, Au, Ni, V, Pt, Pd, or a combination thereof. A silicone lens 602 is molded over support 608 to encapsulate LED die 606 and wavelength converting element 620.

Reflector 604 has one or more angled reflective surfaces 622 covered with a reflective coating 624. Reflective coating 624 may be a thin metal film such as Al, Ag, Cr, Au, Ni, V, Pt, Pd, or a combination thereof. Reflective coating 624 may be the same material coating 618, and they may be applied at the same time.

Reflective surfaces 622 reflects light emitted from LED die 606 or wavelength converting element 620 to limit the emission angle of LED package 600, as demonstrated by light rays 626 and 628. The shape of reflective surfaces 622 depends on the desired emission angle of LED package 600. Reflective surfaces 622 may be flat or curved, and they may be asymmetrical (as demonstrated by reflective surface 622 and phantom reflective surface 622A). Reflector 604 defines a cup for receiving LED die 606 and wavelength converting element 620. The shape of reflector 604 and reflective surfaces 622 may be determined using an optical design software, such as LightTools from Optical Research Associates of Pasadena, Calif.

FIG. 7 is a flowchart of a method for fabricating the LED package 600 in one or more embodiments of the present disclosure. In process 702, support 608 is fabricated with reflector 604 having angled reflective surface 622 and a cup for receiving LED die 606. Process 702 is followed by process 704.

In process 704, LED 606 is mounted to support 608 in the cup defined by reflector 604. Wavelength converting element 620 may be formed on or bonded to the top of LED 606 before the LED is mounted on support 608. Process 704 is followed by process 706.

In process 706, coating 618 is applied to the lateral sides of LED die 606 and wavelength converting element 620, and coating 624 is applied over reflective surface 622. Process 706 is followed by process 708.

In process 708, lens 602 is molded over support 608 to encapsulate LED 606 and wavelength converting element 620 to complete LED package 600.

Various other adaptations and combinations of features of the embodiments disclosed are within the scope of the invention. Numerous embodiments are encompassed by the following claims.

What is claimed is:

1: A light emitting diode (LED) package, comprising:
a support;
an LED die mounted on the support, the LED die comprising a stack of semiconductor layers including an active region;
a reflector around the LED die, the reflector comprising a reflective surface that limits a light emission angle from the LED package; and
a lens mounted on one or more of the support and the LED die, the lens encapsulating the LED die, wherein the reflector is a part of the lens or the support.

2: The LED package of claim 1, wherein the reflector comprises a cavity defined in a bottom surface of the lens, and the cavity is filled with air or a material having a lower refractive index than the lens to form the reflective surface using total internal reflection.

3: The LED package of claim 2, wherein the lens comprises glass.

4: The LED package of claim 1, wherein the reflector comprises a material having a lower refractive index than the lens to form the reflective surface using total internal reflection.

5: The LED package of claim 4, wherein the material includes reflective particles.

6: The LED package of claim 1, further comprising a reflective coating covering the reflective surface.

7: The LED package of claim 6, wherein the reflector comprises an integral part of the support and forms a cup for receiving the LED die.

8: The LED package of claim 1, wherein the reflective surface is flat or curved.

9: The LED package of claim 1, wherein the reflector further comprises another reflective surface that is asymmetrical relative to the reflective surface.

10: A method for fabricating a light emitting diode (LED) package with a support, an LED die, a lens over the LED die, and a reflector that is a part of the lens or the support, the method comprising:
locating the reflector around the LED die so a reflective surface of the reflector extends above a horizontal emitting surface of the LED die to limit light emission angle from the LED package.

11: The method of claim 10, further comprising:
molding the lens to define a cavity; and
filling the cavity with air or a material having a lower refractive index than the lens to form the reflector with the reflective surface using total internal reflection;
wherein locating the reflector around the LED die comprises mounting the lens over the LED die.

12: The method of claim 11, wherein the lens comprises glass.

13: The method of claim 10, wherein locating the reflector around the LED die comprises applying a material having a lower refractive index than the lens around the LED die and molding the material to form the reflector.

14: The method of claim 13, wherein the material includes reflective particles.

15: The method of claim 10, further comprising depositing a reflective coating over the reflective surface.

16: The method of claim 15, further comprising forming the support with the reflector, wherein the reflector forms a cup, wherein locating the reflector around the LED die comprises seating the LED die in the cup.

17: The method of claim 10, wherein the reflective surface is flat or curved.

18: The method of claim 10, wherein the reflector further comprises another reflective surface that is asymmetrical relative to the reflective surface.

19: The method of claim 10, further comprising determining a shape of the reflective surface that produces a desired emission angle of the LED package in consideration of any refraction at an interface between the lens and an intermediate bonding material.

20: The method of claim 19, wherein a refractive index of the intermediate bonding material is less than a refractive index of the lens.
